(19) United States
(12) Patent Application Publication
(10) Pub. No.: US 2009/0180260 A1
(43) Pub. Date: Jul. 16, 2009

(54) MEMORY MODULE, METHOD FOR MANUFACTURING A MEMORY MODULE AND COMPUTER SYSTEM

(75) Inventor: Srdjan Djordjevic, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/972,186

(22) Filed: Jan. 10, 2008

(51) Int. Cl. H05K 1/14; H05K 3/30; H05K 1/11

(52) U.S. Cl. 361/736; 29/852; 29/832; 361/803

(57) ABSTRACT

A memory module, a method for manufacturing a memory module and a computer system is disclosed. One embodiment includes a printed circuit board including a component area and a connector area, wherein a number of signal layers is larger in the component area than in the connector area, the connector area being configured to be plugged into a slot. The memory module further includes memory components mounted on the printed circuit board in the component area.

### BACKGROUND

Embodiments of the invention relate to a memory module, a method for manufacturing a memory module and to a computer system.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a plan view of a memory module according to one embodiment.

FIGS. 2A to 2C illustrate schematic cross-sectional views of printed circuit boards of memory modules according to further embodiments.

FIGS. 3A to 3C illustrate schematic cross-sectional views illustrating layer stacks of printed circuit boards of memory modules according to one or more embodiments.

FIG. 4 illustrates a schematic cross-sectional view illustrating a printed circuit board of a memory module according to one embodiment.

FIG. 5 illustrates a schematic cross-sectional view of a printed circuit board of a memory module according to one embodiment.

FIG. 6 illustrates a schematic view of a computer system according to one embodiment.

FIG. 7 illustrates a flowchart of a method for manufacturing a memory module according to one embodiment.

FIG. 8 illustrates a flowchart of a method for fabricating a memory module according to one embodiment.

FIG. 9 illustrates a flowchart of a method for fabricating a memory module according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

In the following, embodiments are described. It should be noted that all embodiments described in the following may be combined in any way, i.e. there is no limitation that certain described embodiments may not be combined with others. Further, it should be noted that some reference signs throughout the Figures denote same or similar elements. The drawings are not necessarily to scale.

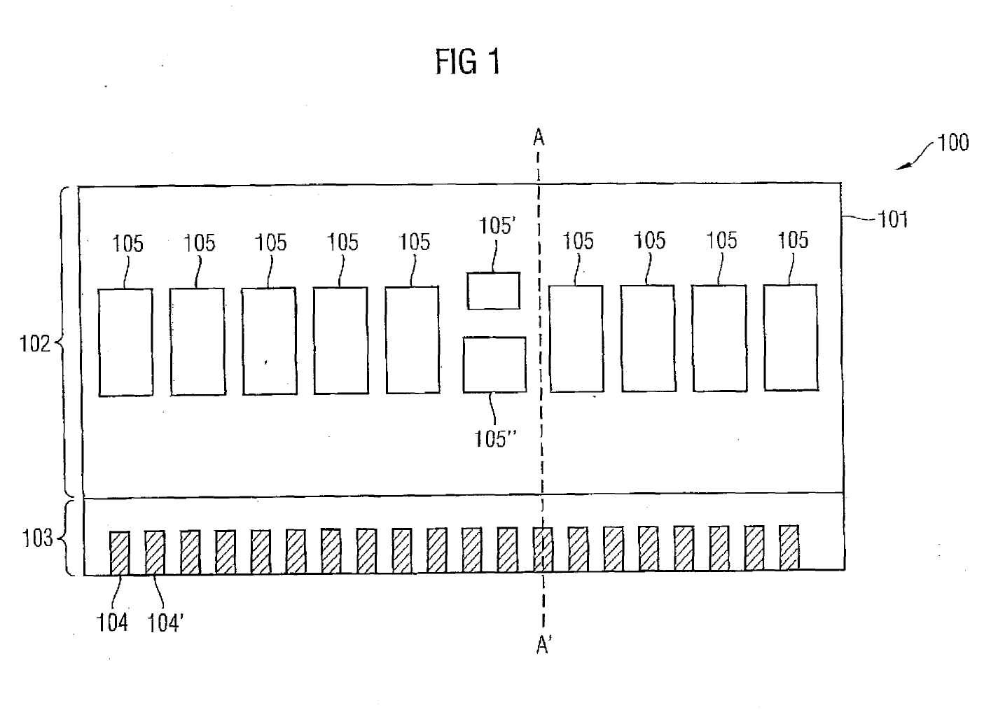

Referring to the schematic plan view of FIG. 1, there is illustrated a memory module 100 according to one embodiment. The memory module 100 includes a printed circuit board 101 that is subdivided into a component area 102 and a connector area 103. The connector area 103 is configured to be plugged into a slot of a circuit board such as a motherboard or a backplane, for example. The printed circuit board 101 may be a multilayer board including multiple signal layers which are electrically isolated from each other by intermediate dielectric layers (not illustrated in plan view of FIG. 1). In the connector area 103, pins 104, 104′, . . . are provided. Memory components 105, 105′, 105″ are mounted on the printed circuit board 101 in the component area 102.

By way of example, the memory components 105, 105′, 105″ may be any of volatile random access memories (volatile RAM) such as static RAM (SRAM) or dynamic random access memories (DRAM) or non-volatile memories such as phase change random access memories (PCRAM), magnetic random access memories (MRAM), ferroelectric random access memories (FRAM, FERAM) or flash memories, for example. The memory components 105, 105′, 105″ may also include further semiconductor chips mounted on the printed circuit board such as advanced memory buffer chips (AMB chips), regulator chips, phase-locked loop chips (PLL chips), for example. Furthermore, the memory components 105, 105′, 105″ may be of stacked, non-stacked or even stacked and non-stacked type and they may include an optional heatspreader. Memory components may be mounted on both or merely on one side of the printed circuit board 101. The memory components may be placed in a row as is illustrated in FIG. 1. However, the memory components may also be placed along multiple rows on the printed circuit board 101. The printed circuit board 101 further includes vias (not illustrated in FIG. 1) which interconnect different signal layers and allow a signal routing from the memory components 105, 105′ and 105″ in the component area 102 to the pins 104, 104′ in the connector area 103. When plugging the memory module 101 into a slot of a circuit board, electrical and physical connection can be achieved between the connector area 103 of the memory module 100 and the slot of the circuit board so that a signal transfer between integrated circuit chips mounted on the circuit board such as a memory controller and the memory components 105, 105′ and 105″ can be established. As an example, signals such as read/write signals, data signals, address signals, clock signals, may be transferred between integrated circuit chips on the circuit board and the memory components 105, 105′ and 105″.

However, the arrangement of the memory components 105, 105′, 105″ in the component area 102 of the printed circuit board 101 is merely an example and there exist many other ways of placing the memory components 105, 105′ and 105″. It is also to be noted that there may also be mounted a different total number of memory components as is illustrated in FIG. 1 and there may also be placed more or less different types of memory components as is illustrated in FIG. 1. In the context of FIG. 1, different types of memory components are denoted by reference signs 105, 105′, 105″.

In addition, the printed circuit board 101 of FIG. 1 includes a thickness that is larger in the component area 102 than in the connector area 103 (not visible in FIG. 1). With regard to the schematic plan view illustrated in FIG. 1, the thickness is measured perpendicular to the drawing plane.

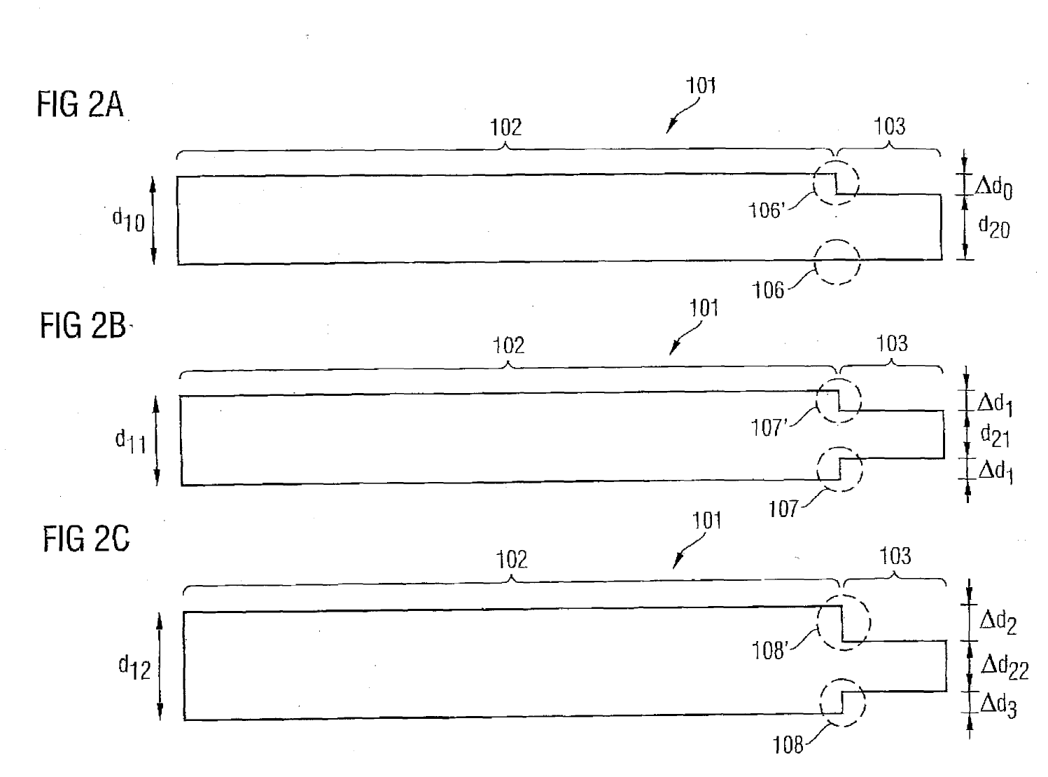

Referring to FIGS. 2A to 2C, schematic cross-sectional views of different embodiments of the printed circuit board 101 are illustrated. The cross-sectional views are taken along a cut line A-A of the printed circuit board 101 illustrated in FIG. 1.

Referring to the schematic cross-sectional view of FIG. 2A, the printed circuit board 101 includes a thickness d₁₀ in the component area 102 that is larger than the thickness d₂₀ in the connector area 103 by an amount of Δd₀=d₁₀−d₂₀. As is illustrated in FIG. 2A, the thickness of the printed circuit board 101 is, with reference to the connector area 103, increased in the component area 102 only with regard to one side, i.e. the other of the both opposing sides of the printed circuit board 101 is plane. Hence, the one side of the printed circuit board 101 includes a process of the amount Δd₀ in a transition region 106′ from the component area 102 to the connector area 103, whereas no process occurs in a transition region 106 from the component area 102 to the connector area 103 on the other side. When fabricating the printed circuit board 101 of FIG. 2A, constraints imposed up on the thickness d₂₀ in the connector area 103, e.g., with regard to fixed thickness measures of slots of circuit boards, and complementary needs with regard to thicker intermediate dielectric layers, e.g., for reducing cross-talk between adjacent signal layers, and with regard to an increased number of signal layers, e.g., for complying with higher data volumes of future memory chip generations, can be given consideration to.

FIG. 2B illustrates a schematic cross-sectional view of the printed circuit board 101 according to one embodiment. The printed circuit board 101 includes a thickness d₁₁ in the component area 102 that is larger than the thickness d₂₁ in the connector area 103 by an amount of 2·Δd₁. The printed circuit board 101 includes a process of an amount of Δd₁ in a transition region 107 from the component area 102 to the connector area 103 on one side and a process of a same amount Δd₁ in a transition region 107′ from the component area 102 to the connector area 103 on the other, i.e. opposing, side. Hence, the thickness of the printed circuit board 101 in the component area 102 is symmetrically increased with regard to both sides.

FIG. 2C illustrates a schematic cross-sectional view of the printed circuit board 101 according to one embodiment. The printed circuit board 101 includes a thickness d₁₂ in the component area 102 that is larger than the thickness d₂₂ in the connector area 103 by an amount of Δd₂+Δd₃=d₁₂−d₂₂. The printed circuit board 101 includes a process of an amount of Δd₂ in a transition region 108′ from the component area 102 to the connector area 103 on one side and a process of an amount of Δd₃ in a transition region 107′ from the component area 102 to the connector area 103 on the other, i.e. opposing, side. Hence, a thickness of the printed circuit board 101 in the component area 102 is not symmetrically increased with regard to both sides.

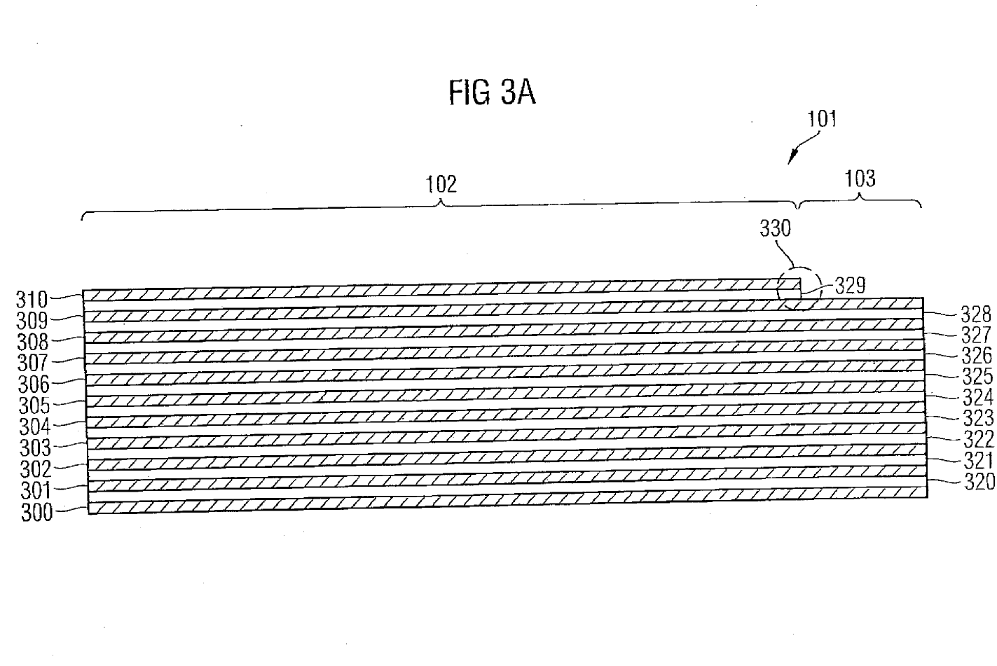

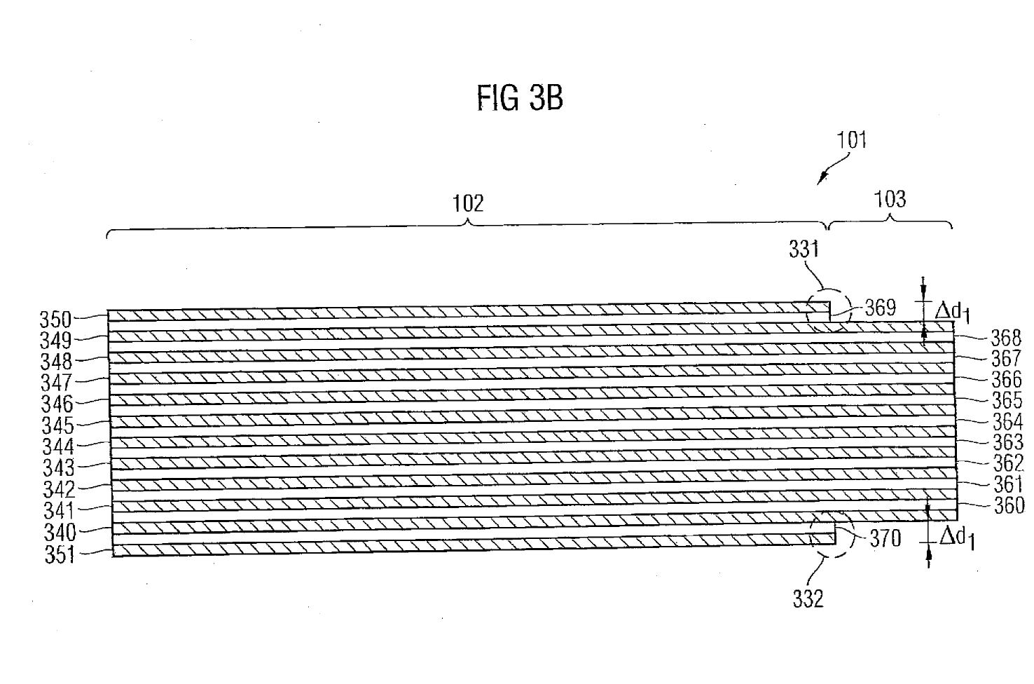

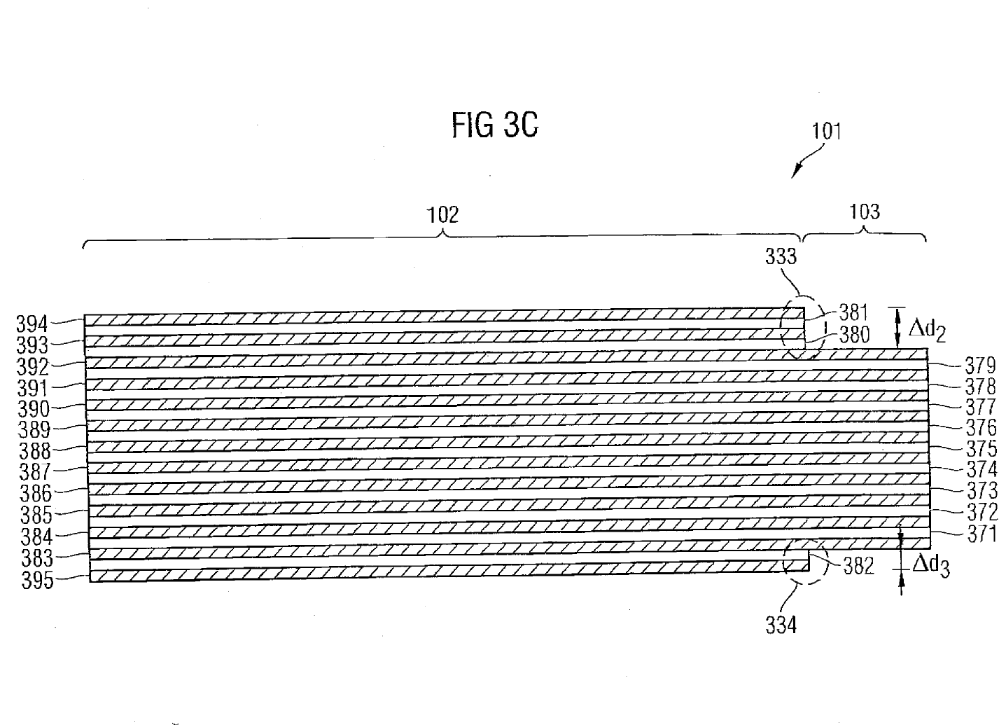

Referring to the schematic cross-sectional view of the printed circuit board 101 illustrated in FIG. 3A, one embodiment is described as an exemplary composition of the printed circuit board illustrated in FIG. 2A. The printed circuit board 101 includes signal layers 300, . . . , 309 and intermediate dielectric layers 320, . . . , 328 sandwiched between adjacent ones of signal layers 300, . . . , 309. The signal layers 300, . . . , 309 are plane and common to the component area 102 and the connector area 103. Each of the signal layers 300, . . . , 309 may be a patterned conductive layer. By way of example, the signal layers may be of copper and they may be patterned by subtractive methods such as silk screen printing, photoengraving, PCB milling or any other suitable process leaving only desired copper traces. By way of example, the intermediate dielectric layers 320, . . . , 328 may be formed of any suitable dielectric material such as FR-4, Epoxy PPO/CE, Polyimide, BT resin. Although the number of signal layers 300, . . . , 309 common to the printed circuit board 101 in the component area 102 and the connector area 103 amounts up to 10, this number is merely to be considered as an example and naturally other numbers of signal layers may be realized. As an example, eight, nine, eleven or twelve signal layers may be used common to the component area 102 and the connector area 103. The thickness of the signal layers 300, . . . , 309 may be equally chosen. However, the thickness of these layers 300, . . . , 309 may also partly or completely differ from each other. By way of example, the thickness of the outermost signal layer 300 common to the component area 102 and the connector area 103 may be thicker than inner signal layers, e.g., signal layers 301 or 302. As a further example, signal layer 309 constituting an outermost signal layer in the connector area 103 may also be chosen thicker than inner signal layers, e.g., signal layers 307 and 306. Similarly, the thickness of the intermediate dielectric layers 320, . . . , 328 may also differ from each other.

In addition to the signal layers 300, . . . , 309 and the intermediate dielectric layers 320, . . . , 328, which are common to the component area 102 and the connector area 103, a further intermediate dielectric layer 329 is provided on the signal layer 309 in the component area 102. On the additional intermediate dielectric layer 329, there is provided a further signal layer 310 forming an outermost signal layer in the component area 102. Thus, the layer stack of successive signal layers 300, . . . , 310 and intermediate dielectric layers 320, . . . , 329 is locally increased in the component area 102 leaving a process in a transition region 330 from the component area 102 to the connector area 103. Similarly to the above, the thickness of the additional layers 329, 310 may be chosen in any appropriate way. By way of example, the thickness of the outermost signal layer 310 in the connector area 102 may be chosen thicker compared to an inner signal layer, e.g., signal layer 308 or 307. It is to be noted that an amount of the thicknesses of all layers constituting the connector area 103, i.e. signal layers 300, . . . , 309 and intermediate dielectric layers 320, . . . , 328 may be restricted with regard to the slot of a circuit board into which the memory module has to be plugged. By way of example, the thickness of the layer stack may amount up to 1.27 mm in the connector area 103.

Referring to the schematic cross-sectional view of the printed circuit board 101 illustrated in FIG. 3B, one embodiment is described as an exemplary composition of the printed circuit board as illustrated in FIG. 2B. The printed circuit board 101 includes signal layers 340, . . . , 349 and intermediate dielectric layers 360, . . . , 368 sandwiched between adjacent ones of the signal layers 340, . . . , 349. The signal layers 340, . . . , 349 are plane and common to the component area 102 and the connector area 103.

In addition to the signal layers 340, . . . , 349 and the intermediate dielectric layers 360, . . . , 368, a further intermediate dielectric layer 369 is provided on the signal layer 349 with regard to one side of the component area 102. On the additional intermediate dielectric layer 369, there is provided a further signal layer 350 forming the outermost signal layer on the one side of the component area 102. In addition, yet another intermediate dielectric layer 370 is provided on the signal layer 340 with regard to the other side of the component area 102. On the intermediate dielectric layer 370, there is provided a further signal layer 351 forming the outermost signal layer on the other side of the component area 102. Thus, the layer stack of successive signal layers 351, 340, . . . , 350 and intermediate dielectric layers 370, 360, . . . , 369 is locally increased in the component area 102 leaving a process of an amount of Δd₁ in the transition region 331 from the component area 102 to the connector area 103 on the one side of the printed circuit board 161 and a process of a same amount of Δd₁ in the transition region 332 from the component area 102 to the connector area 103 on the other side of the printed circuit board 101. With regard to the variety of number, thickness, fabrication method, material of the signal layers 340, . . . , 351 and the intermediate dielectric layers 360, . . . 370, reference is taken to the elucidations in conjunction with the embodiment illustrated in FIG. 3A.

Referring to the schematic cross-sectional view of the printed circuit board 101 illustrated in FIG. 3C, one embodiment is described as an exemplary composition of the printed circuit board illustrated in FIG. 2C. The printed circuit board 101 includes signal layers 383, . . . , 392 and intermediate dielectric layers 371, . . . , 379 sandwiched between adjacent ones of the signal layers 383, . . . , 392. The signal layers 383, . . . , 392 are plane and common to the component area 102 and the connector area 103.

In addition to the signal layers 383, . . . , 392 as well as the intermediate dielectric layers 371, . . . , 379, a further stack of intermediate dielectric layers 380, 381 and signal layers 393, 394 is provided on signal layer 391 with regard to one side of the component area 102. In addition, yet another intermediate dielectric layer 382 is provided on signal layer 383 with regard to the other side of the component area 102. On dielectric layer 382, there is provided a further signal layer 395 forming the outermost signal layer on the other side of the component area 102. Thus, the layer stack of successive signal layers 395, 383, . . . , 394 and intermediate dielectric layers 382, 371, . . . , 381 is locally increased in the component area 102 leaving a process of an amount of Δd₂ in the transition region 333 from the component area 102 to the connector area 103 on one side of the printed circuit board 101 and a process of a different amount of Δd₃ in the transition region 334 from the component area 102 to the connector area 103 on other side of the printed circuit board 101. With regard to the variety of number, thickness, fabrication method, material of the signal layers 383, . . . , 394, and the intermediate dielectric layers 371, . . . , 382, reference is taken to the elucidations in conjunction with the embodiment illustrated in FIG. 3A.

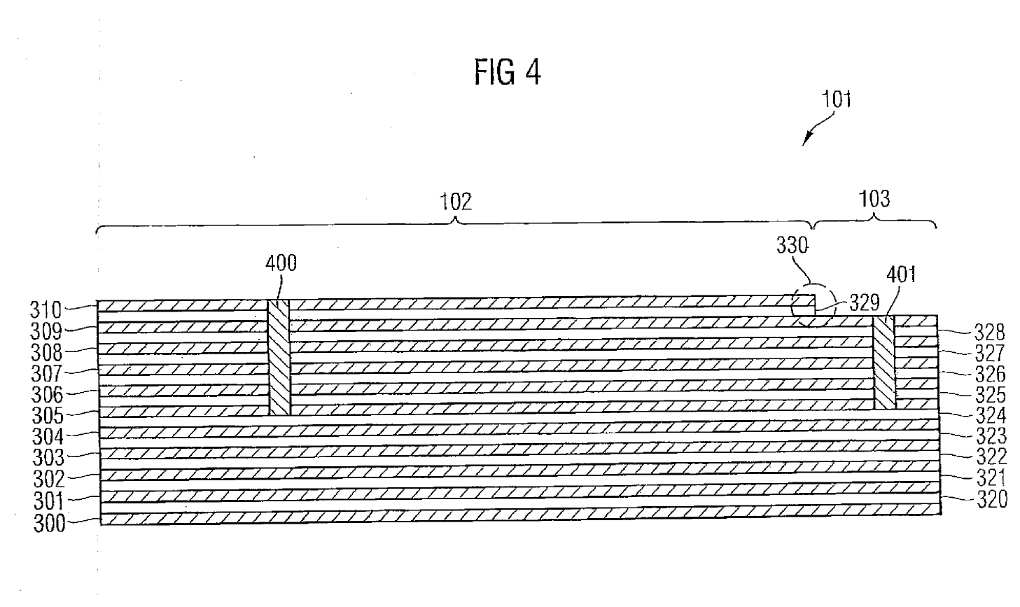

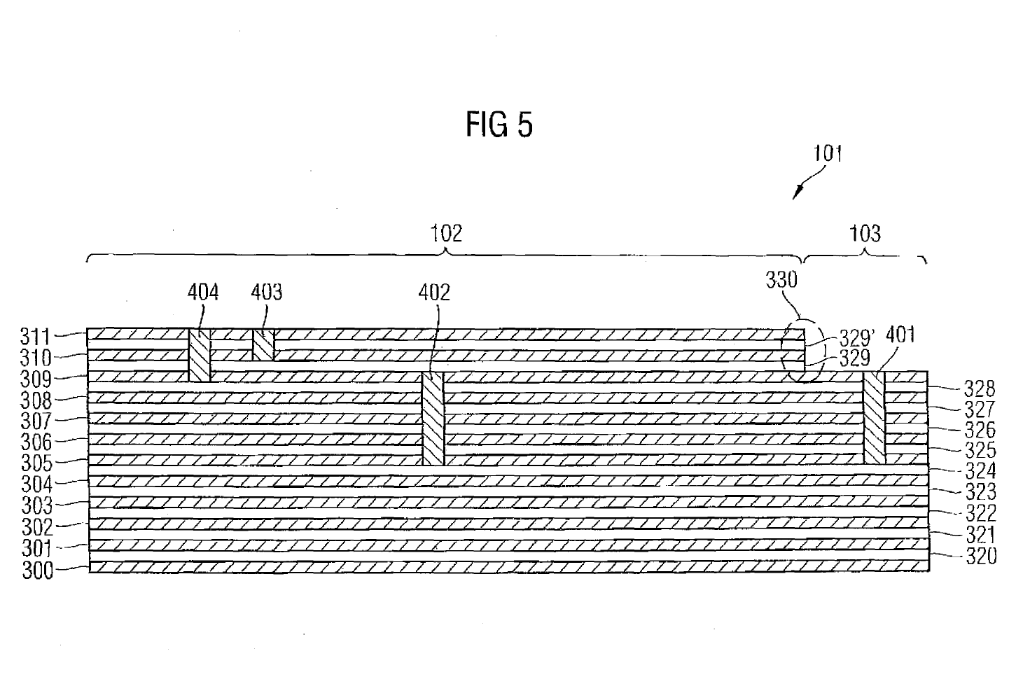

Referring to the schematic cross-sectional view of FIG. 4, there is illustrated a printed circuit board 101 of a memory module according to a further embodiment. The printed circuit board 101 includes a layer stack of signal layers 301, . . . , 310 and intermediate dielectric layers 320, . . . , 329. The intermediate dielectric layer 329 and the signal layer 310 are merely formed in the component area 102 leaving the connector area 103 thinner than the component area 102. The printed circuit board 101 further includes vias 400, 401 configured to interconnect different ones of the signal layers 300, . . . , 310. It is to be noted that the number of vias formed in the printed circuit board 101 is not restricted to vias 400, 401. Each via in the component area 102, e.g., via 400, that is connected to a signal layer common to the component area and the connector area, e.g., signal layer 305, further extends to an outermost signal layer in the component area 102, e.g., signal layer 310. Hence, drilling of the vias in the component area 102 is carried out after completing the layer stack of the printed circuit board 101 in this area.

Referring to the schematic cross-sectional view of FIG. 5, there is illustrated a printed circuit board 101 of a memory module according to one embodiment. The printed circuit board 101 includes a layer stack of signal layers 300, . . . , 311 and intermediate dielectric layers 320, . . . , 329, 329′, whereas signal layers 310, 311 and intermediate dielectric layers 329, 329′ are merely formed in the component area 102 resulting in a process 330 in the transition region 330 from the component area 102 to the connector area 103. With regard to vias 402, 404 and 403 drilled in the component area 102, at least one of these vias connected to a signal layer in the component area 102 and the connector area 103, e.g., signal layer 305, ends before an outermost signal layer 311 in the component area 102. Hence, part of the vias, e.g., via 402, are drilled in the component area 102 before completing the layer stack of the printed circuit board 101. These vias may be drilled together with the vias in the connector area 103, e.g., together with via 401. After completion of the layer stack, as regards the component area 102, further vias, e.g., vias 403, 404 may be drilled in the component area 102. By way of example, drilling of the vias may be carried out by mechanical drilling or laser drilling. However, further methods may be used to fabricate the vias. The embodiment of the printed circuit board 101 illustrated in FIG. 5 may thus include blind vias, e.g., vias 403, 404, and buried vias, e.g., via 402, or even through-hole vias (not illustrated).

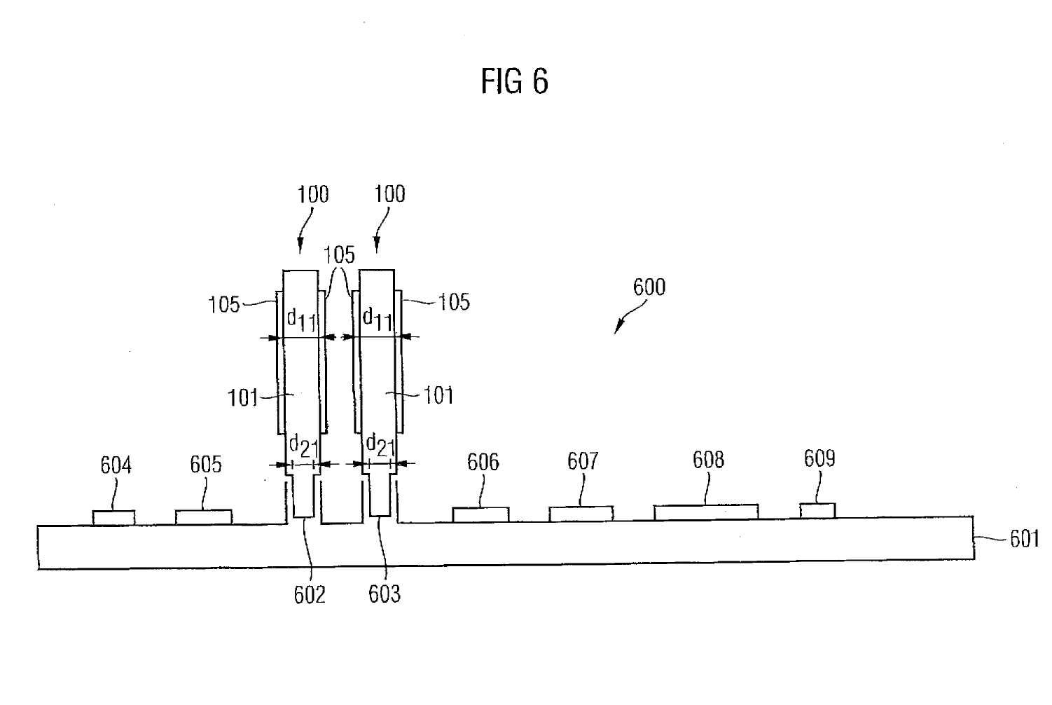

Referring to the schematic view illustrated in FIG. 6, a computer system 600 according to one embodiment is elucidated. The computer system 600 includes a circuit board 601 having slots 602, 603 as well as further circuit board elements 604, . . . , 609. The computer system 600 may be a personal computer, a work station or any other system manipulating data according to a list of instructions. By way of example, the circuit board 601 may be a motherboard or a backplane. As a further example, the circuit board elements 604, . . . , 609 may include sockets, in which one or more CPUs are installed, a chip set, non-volatile memory chips, a clock generator, slots for expansion cards, or power connectors.

The computer system 600 further includes memory modules 100 having memory components 105 mounted on respective printed circuit boards 101. The memory modules 100 are plugged into the slots 602, 603 of the circuit board 601. As is illustrated in FIG. 6, each printed circuit board 101 includes a thickness that is larger in an area where the memory components 105 are mounted on the board 101, e.g. a thickness d₁₁, than in the area where boards 101 are plugged into the slots 602, 603 of the circuit board 601, e.g. a thickness d₂₁. Although two identical memory modules 100 are illustrated in FIG. 6, a different number of memory modules and also different types of memory modules may be used.

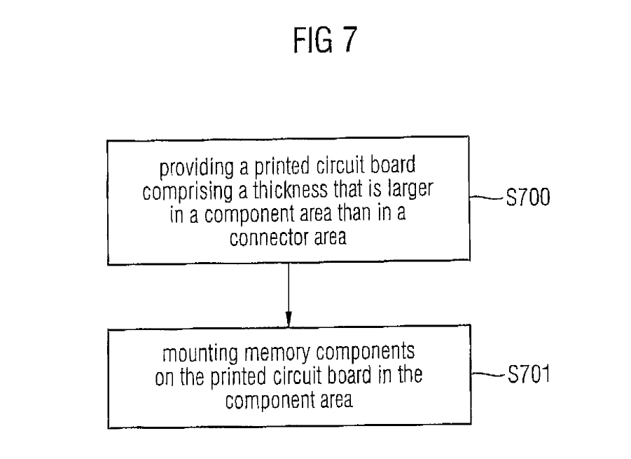

In FIG. 7, features of a method for manufacturing a memory module according to one embodiment are illustrated by using a flowchart.

At S700, there is provided a printed circuit board including a thickness that is larger in a component area than in a connector area, the connector area being configured to be plugged into a slot. Then, at S701, memory components are mounted on the printed circuit board in the component area.

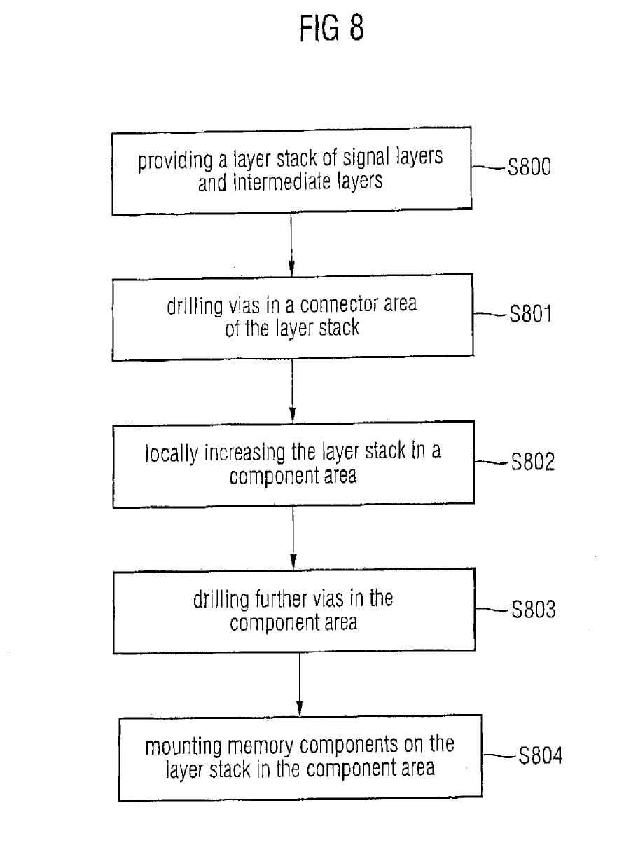

Referring to the schematic flow chart illustrated in FIG. 8, features of a method for manufacturing a memory module according to one embodiment are illustrated. At S800, a layer stack of signal layers and intermediate layers is provided. Then, at S801, vias are drilled in a connector area of the layer stack. Thereafter, at S802, the layer stack is locally increased in a component area. At S803, further vias are drilled in the component area. Thereafter, at 804, memory components are mounted on the layer stack in the component area.

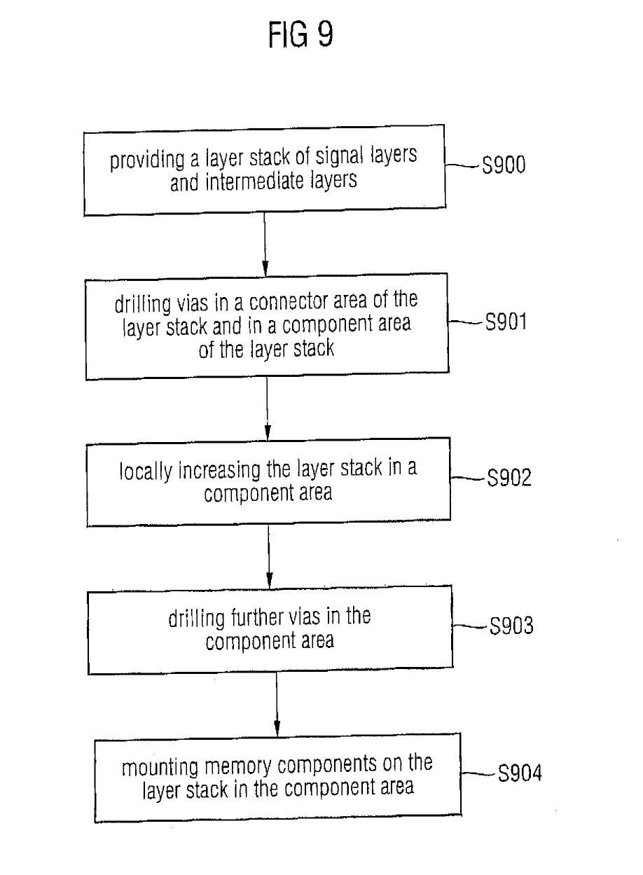

In the schematic flowchart illustrated in FIG. 9, features of a method for manufacturing a memory module according to one embodiment are described. As regards to S900, S902, S903 and S904, reference is taken to the corresponding method S800, S802, S803 and S804 described with regard to FIG. 8. However, method S901 differs from method S801 in that, before locally increasing the layer stack in a component area, vias are not only drilled in the connector area as described in S801, but also in the component area.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory module, comprising:
a printed circuit board including signal layers and intermediate dielectric layers, the printed circuit board further including a connector area and a component area, wherein the connector area is configured to be plugged into a slot of a circuit board; and
memory components mounted on the printed circuit board in the component area, wherein a number of the signal layers is larger in the component area than in the connector area.

2. The memory module of claim 1, comprising wherein a thickness of the component area is larger than a thickness of the connector area.

3. The memory module of claim 1, comprising wherein the signal layers and the intermediate dielectric layers are plane layers consecutively stacked on each other.

4. The memory module of claim 1, further comprising:
a signal layer common to the connector area; and
the component area as an outermost signal layer.

5. The memory module of claim 1, comprising wherein a number of additional signal layers from an outermost signal layer of the connector area to an outermost signal layer of the component area differs with regard to opposing sides of the printed circuit board.

6. The memory module of claim 1, comprising wherein a number of additional signal layers from an outermost signal layer of the connector area to an outermost signal layer of the component area is equal with regard to opposing sides of the printed circuit board.

7. The memory module of claim 1, comprising wherein a thickness of the printed circuit board equals 1.27 mm in the connector area and more than 1.27 mm in the component area.

8. The memory module of claim 1, comprising wherein a number of signal layers equals 10 in the connector area and at least 12 in the component area.

9. The memory module of claim 1, wherein the number of signal layers equals 14 in the component area.

10. The memory module of claim 1, comprising wherein the printed circuit board further includes vias configured to interconnect different ones of the signals layers, and wherein each via in the component area that is connected to a signal layer being common to the component area and the connector area further extends to an outermost signal layer in the component area.

11. The memory module of claim 1, comprising wherein the printed circuit board further includes vias configured to interconnect different ones of the signal layers, and wherein at least one via connected to a signal layer in the component area, the signal layer being common to the component area and the connector area, ends before an outermost signal layer in the component area.

12. A memory module, comprising:
a printed circuit board including a component area and a connector area, wherein a thickness of the component area is larger than a thickness of the connector area, the connector area being configured to be plugged into a slot; and
memory components mounted on the printed circuit board in the component area.

13. A method for manufacturing a memory module, comprising:
providing a layer stack of signal layers and intermediate dielectric layers;
drilling vias in a connector area of the layer stack, the connector area being configured to be plugged into a slot;
locally increasing the layer stack in a component area by providing at least one additional signal layer and at least one additional intermediate dielectric layer, the component area being different from the connector area;
drilling further vias in the component area of the layer stack; and
mounting memory components on the layer stack in the component area.

14. The method of claim 13, comprising wherein, when drilling the vias in the connector area, vias are also drilled in the component area.

15. The method of claim 13, comprising carrying out the feature of increasing the layer stack with regard to one of both sides of the layer stack.

16. The method of claim 13, comprising carrying out the feature of increasing the layer stack with regard to both sides of the layer stack.

17. A method for fabricating a memory module, comprising:
providing a printed circuit board including a component area and a connector area, wherein a thickness of the component area is larger than a thickness of the connector area, the connector area being configured to be plugged into a slot; and
mounting memory components on the printed circuit board in the component area.

18. A System, comprising:
a printed circuit board including a component area and a connector area, wherein a thickness of the component area is larger than a thickness of the connector area;
memory components mounted on the printed circuit board in the component area;
a circuit board comprising a slot, the printed circuit board being plugged into the slot with its connector area.

19. The system of claim 18, wherein the system comprises a computer system.

20. The system of claim 18, comprising:
the printed circuit board including signal areas and intermediate dielectric areas that are plane layers stacked on each other.
